(19) United States
(12) Patent Application Publication
(10) Pub. No.: US 2025/0028237 A1
(43) Pub. Date: Jan. 23, 2025

(54) METHOD FOR MANUFACTURING GRAPHENE THIN FILM FOR PELLICLE MATERIAL USING OZONE GAS

(71) Applicant: GrapheneLab.Co.,Ltd, Hwaseong-si (KR)

(72) Inventors: Gyu Hyun LEE, Yongin-si (KR); Young Duck KWON, Gwangmyeong-si (KR); Byong Wook YOO, Namyangju-si (KR); Seung Il MOON, Ansan-si (KR); Jong Taik MOON, Seongnam-si (KR); Ki Soo KIM, Seongnam-si (KR); Sang Min LEE, Yongin-si (KR)

(21) Appl. No.: 18/905,115

(22) Filed: Oct. 2, 2024

Related U.S. Application Data
(63) Continuation of application No. PCT/KR2023/005097, filed on Apr. 14, 2023.

(30) Foreign Application Priority Data
Apr. 15, 2022 (KR) 10-2022-0046796

(51) Int. Cl. G03F 1/62

(52) U.S. Cl. CPC G03F 1/62

(57) ABSTRACT

A method for manufacturing a graphene thin film for a pellicle material using ozone gas includes a graphene forming step of forming graphene on an upper surface of a substrate, an ozone treatment step of exposing the graphene layer formed in the graphene forming step to ozone, and an etching step of heat-treating and etching the ozone-treated graphene layer.

### CROSS-REFERENCE TO RELATED APPLICATIONS

This application is a Continuation of International Application No. PCT/KR2023/005097 filed Apr. 14, 2023, which claims priority from Korean Application No. 10-2022-0046796 filed Apr. 15, 2022. The aforementioned applications are incorporated herein by reference in their entireties.

### TECHNICAL FIELD

The present disclosure relates generally to a method for manufacturing a graphene thin film for a pellicle material using ozone gas. More particularly, the present disclosure relates to a method for manufacturing a graphene thin film for a pellicle material using ozone gas, the method being capable of enabling easy control of the thickness of a graphene thin film, and provides a graphene thin film which exhibits excellent extreme ultraviolet (EUV) transmittance and uniformity, maintains mechanical strength because damage to a graphene layer is suppressed during an etching process, and on which a capping layer can be uniformly deposited through surface functionalization.

### RELATED ART

As the semiconductor industry develops and integration of semiconductor devices improves, electronic devices are becoming smaller and lighter. To improve integration of semiconductor devices, advancement of exposure technology is also required.

Recently, technologies have been developing to realize fine patterns of semiconductors by reducing the wavelength of a light source. Of these, extreme ultraviolet exposure technology known as next-generation technology can create fine patterns with a single resist process. An extreme ultraviolet exposure device used in a semiconductor process generally includes a light source power, a resist, a pellicle, and a mask.

The pellicle is installed on the mask to prevent foreign substances generated during an exposure process from being attached to the mask, and is selectively used depending on the type of exposure device. In an extreme ultraviolet exposure process, there was an initial expectation that a clean system would be built and a pellicle would not be necessary, but in reality, after an exposure device was built and operated, it was confirmed that the mask was contaminated by foreign substances generated from an internal driving part of the device, tin particles generated during a light source generation process, and an extreme ultraviolet photoresist. Therefore, a pellicle is recognized as an essential material to prevent mask contamination in an extreme ultraviolet exposure process.

Currently, domestic and foreign pellicle developers are developing transparent materials based on polycrystalline silicon (p-Si) or SiN. However, these materials do not satisfy a transmittance of over 90%, which the most important condition for a pellicle for extreme ultraviolet light. Additionally, since these materials have vulnerabilities in thermal stability, mechanical stability, and chemical durability in extreme ultraviolet exposure environments, research is being conducted to develop processes to improve characteristics.

In an effort to solve the above problems, attempts have been made to develop graphene-based pellicles for extreme ultraviolet light. Graphene has a transmittance of over 90% for extreme ultraviolet light and, at the same time, has a very high tensile strength when the basal planes of graphene are arranged in the same manner in a planar direction, so it can satisfy all characteristic indicators such as high transmittance, thermal stability, and mechanical stability.

Meanwhile, there are already various methods known for forming a graphene thin film layer by direct growth at low temperature. When catalyst metal and amorphous carbon are subjected to heat treatment, interlayer switching occurs, forming graphene. At this time, the temperature for heat treatment is generally lower by 400° C. to 500° C. compared to a conventional CVD method that forms graphene by thermal decomposition of methane. Additionally, graphene has the advantage of having a uniform thickness in terms of its formation mechanism characteristics.

Due to these advantages, graphene has recently been in the spotlight as an extreme ultraviolet pellicle core material, but there are problems that have to be solved for it to be applied as pellicles.

First, in order to use graphene as a pellicle, the thickness of graphene needs to be 10 to 15 nm, but the minimum thickness of graphene formed by a low-temperature direct growth method is about 30 nm. This is because the thickness of graphene is determined by the thickness of catalyst metal and amorphous carbon, and a thin catalyst metal film is heat-treated on an inert substrate and formed into an agglomeration.

In order to solve the above problem, a method for etching graphene formed to about 30 nm is required. However, since graphene has a chemically stable surface, there is a limit to etching graphene using a wet etching method.

Additionally, there is a method using oxygen plasma (O-plasma) or argon plasma (Ar plasma) for dry etching. Oxygen plasma is a chemical etching method using radicals and enables fast etching because of its excellent oxidizing power, but is problematic in that a graphene layer becomes uneven. Argon plasma is a physical etching method using ion bombardment, and is problematic in that the stress applied to a graphene surface increases as the treatment time increases, causing a graphene thin film to sag after etching.

### SUMMARY

Accordingly, the present disclosure has been made keeping in mind the above problems occurring in the related art, and an objective of the present disclosure is to provide a method for manufacturing a graphene thin film for a pellicle material using ozone gas, the method being capable of enabling easy control of the thickness of a graphene thin film, and provides a graphene thin film which exhibits excellent extreme ultraviolet transmittance and uniformity, maintains mechanical strength because damage to a graphene layer is suppressed during an etching process, and on which a capping layer can be uniformly deposited though surface functionalization.

In order to accomplish the above objective, the present disclosure provides a

method for manufacturing a graphene thin film for a pellicle material using ozone gas, the method including: a graphene forming step of forming graphene on an upper surface of a substrate; an ozone treatment step of exposing the graphene layer formed in the graphene forming step to ozone; and an etching step of heat-treating and etching the ozone-treated graphene layer.

According to a preferred feature of the present disclosure, the ozone treatment step may be performed by exposing the graphene layer formed in the graphene forming step to ozone at 100° C. to 400° C. for 10 to 600 seconds in an oxygen mixture gas atmosphere.

According to a more preferred feature of the present disclosure, the oxygen mixture gas may be composed of oxygen and nitrogen in a weight ratio of 97:3 and is injected at 900 to 1100 sccm.

According to a more preferred feature of the present disclosure, the ozone may have a concentration of 50 to 500 g/Nm³.

According to a more preferred feature of the present disclosure, the etching step may be performed by heat-treating the graphene layer ozone-treated in the ozone treatment step at 400° C. to 1000° C. for 1 to 120 minutes in a hydrogen gas atmosphere.

According to a more preferred feature of the present disclosure, the hydrogen gas may be injected at 10 to 500 sccm.

According to a more preferred feature of the present disclosure, the ozone treatment step and the etching step may be repeated until a thickness of the graphene film manufactured through the etching step reaches 10 to 15 nm.

A method for manufacturing a graphene thin film for a pellicle material using ozone gas according to the present disclosure has the advantages of enabling easy control of the thickness of the graphene thin film, and providing a graphene thin film which exhibits excellent extreme ultraviolet transmittance and uniformity, maintains mechanical strength because damage to the graphene layer is suppressed during the etching process, and on which a capping layer can be uniformly deposited though surface functionalization.

### BRIEF DESCRIPTION OF THE DRAWINGS

FIG. 1 illustrates a flowchart of a method for manufacturing a graphene thin film for a pellicle material using ozone gas according to the present disclosure.

FIG. 2 illustrates images of graphene thin films manufactured through Examples 1 to 8 of the present disclosure taken using a scanning electron microscope (SEM).

FIGS. 3 to 6 illustrates images of graphene thin films manufactured through Examples 1 to 8 of the present disclosure analyzed by Raman spectroscopy and graphs showing the results of analysis.

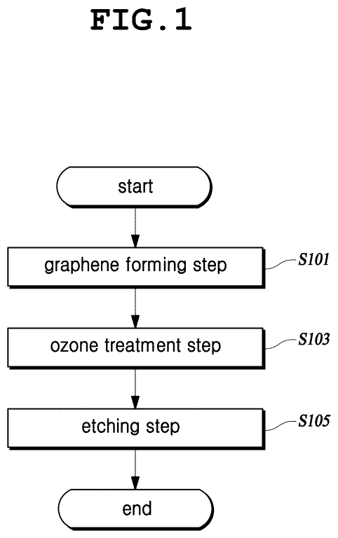

### DETAILED DESCRIPTION

Hereinafter, exemplary embodiments of the present disclosure will be described in detail. However, they are only intended to describe the present disclosure in detail such that those of ordinary skill in the art to which the present disclosure belongs can easily carry out the present disclosure and the technical idea and scope of the present disclosure are not limited by them.

A method for manufacturing a graphene thin film for a pellicle material using ozone gas according to the present disclosure includes: a graphene forming step S101 of forming graphene on an upper surface of a substrate; an ozone treatment step S103 of exposing the graphene layer formed in the graphene forming step to ozone; and an etching step S105 of heat-treating and etching the ozone-treated graphene layer.

The graphene forming step S101 is a step for forming graphene on the upper surface of the substrate. A method for forming graphene on the upper surface of the substrate is not particularly limited and various methods may be used. However, it is preferable to use a low-temperature direct growth method that forms a graphene layer of uniform thickness and provides graphene suitable as a pellicle material.

More specifically, the low-temperature direct growth method may include: forming few-layer graphene on a silicon nitride substrate; forming a metal catalyst layer on an upper surface of the few-layer graphene; forming an amorphous carbon layer on an upper surface of the metal catalyst layer; and performing heat treatment using the few-layer graphene as a seed layer so that carbon of the amorphous carbon layer passes through the metal catalyst layer and moves onto the few-layer graphene through interlayer switching between the metal catalyst layer and the amorphous carbon layer, thereby directly growing the few-layer graphene into multi-layer graphene.

At this time, the few-layer graphene is a seed layer of the multi-layer graphene and serves as a diffusion prevention layer that prevents metal of the metal catalyst layer from diffusing onto the silicon nitride substrate.

Additionally, the material of the metal catalyst layer may include Ni, Co, Ru, or Pt. In the process of forming the metal catalyst layer, it is preferable that the metal catalyst layer is formed to a thickness of 10 nm to 100 nm through sputtering or an e-beam evaporation method.

Additionally, in the process of forming the amorphous carbon layer, it is preferable that the amorphous carbon layer is formed to a thickness of 10 nm to 100 nm through sputtering.

Additionally, in the process of directly growing the multi-layer graphene, it is preferable that heat treatment is performed at 500° C. to 1100° C. for 10 minutes to 10 hours in a hydrogen and inert gas atmosphere, and it is preferable that the inert gas is at least one selected from the group consisting of nitrogen, argon, and helium. Additionally, after the process of directly growing multi-layer graphene, a step of removing the metal catalyst layer formed on the upper surface of the multi-layer graphene may be performed.

The ozone treatment step S103 is a step for exposing the graphene layer formed in the graphene forming step S101 to ozone. The ozone treatment step S103 includes exposing the graphene layer formed in the graphene forming step S101 to ozone at 100° C. to 400° C. for 10 to 600 seconds in an oxygen mixture gas atmosphere.

The graphene layer formed in the above graphene forming step is formed with a thickness of 30 to 50 nm, so in order to apply it as a pellicle material, the thickness needs to be reduced to 10 to 15 nm. Through ozone treatment including the above process, ozone molecules are physisorbed on the basal plane of the graphene layer, and the physisorbed ozone chemically reacts with graphene to form an epoxide group and an oxygen molecule.

More specifically, through the ozone treatment step S103 including the above process, C═C SP2 hybridization bonds of graphene are destroyed, generating C═O and C—O—H.

At this time, the oxygen mixture gas is formed by mixing oxygen and nitrogen in a weight ratio of 97:3, and is preferably injected at 900 to 1100 sccm, and it is more preferable that the ozone has a concentration of 50 to 500 g/Nm³.

The graphene layer ozone-treated in the ozone treatment step S103 performed under the above conditions may be removed through a heat treatment process performed in the etching step S105.

The etching step S105 is a step for heat-treating and etching the graphene layer ozone-treated in the ozone treatment step S103. The graphene layer ozone-treated in the ozone treatment step S103 is heat-treated at 400° C. to 1000° C. for 1 to 120 minutes in a hydrogen gas atmosphere. At this time, it is preferable that the hydrogen gas is injected at 10 to 500 sccm.

Through the etching step S105 including the above process, the outermost layer of graphene on which the epoxide group is formed is removed, thereby reducing the thickness of the graphene layer.

More specifically, C═O and C—O—H generated on the surface of graphene through the ozone treatment step S103 are removed by high-temperature heat treatment, generating carbon dioxide and carbon monoxide gases.

At this time, since the outermost layer of graphene is removed layer by layer through the etching step S105, when the thickness of the graphene layer does not reach 10 to 15 nm, it is preferable to repeat the ozone treatment step S103 and the etching step S105 until the above thickness range is reached.

Hereinafter, a method for manufacturing a graphene thin film for a pellicle material using ozone gas according to the present disclosure and the properties of a graphene thin film manufactured by the method will be described with examples.

### Example 1

Few-layer graphene was formed on a silicon nitride substrate. A metal catalyst layer was formed on an upper surface of the few-layer graphene. An amorphous carbon layer was formed on an upper surface of the metal catalyst layer. Heat treatment was performed using the few-layer graphene as a seed layer so that carbon of the amorphous carbon layer passed through the metal catalyst layer and moved onto the few-layer graphene through interlayer switching between the metal catalyst layer and the amorphous carbon layer, thereby directly growing the few-layer graphene into multi-layer graphene. With this process, two-layer graphene was formed. The resulting graphene layer was exposed to ozone (250 g/Nm³) for 30 seconds at 200° C. in an atmosphere of 1000 sccm of oxygen mixture gas (oxygen and nitrogen mixed in a weight ratio of 97:3), and then heat-treated for 60 minutes at 700° C. in a hydrogen gas atmosphere (250 sccm), thereby manufacturing a graphene thin film for a pellicle material.

### Example 2

A graphene thin film for a pellicle material was manufactured in the same manner as in Example 1, except that the graphene layer was exposed to ozone for 60 seconds.

### Example 3

A graphene thin film for a pellicle material was manufactured in the same manner as in Example 1, except that the graphene layer was exposed to ozone at 250° C.

### Example 4

A graphene thin film for a pellicle material was manufactured in the same manner as in Example 1, except that the graphene layer was exposed to ozone at 250° C. for 60 seconds.

### Example 5

A graphene thin film for a pellicle material was manufactured in the same manner as in Example 1, except that three-layer graphene was formed.

### Example 6

A graphene thin film for a pellicle material was manufactured in the same manner as in Example 2, except that three-layer graphene was formed.

### Example 7

A graphene thin film for a pellicle material was manufactured in the same manner as in Example 3, except that three-layer graphene was formed.

### Example 8

A graphene thin film for a pellicle material was manufactured in the same manner as in Example 4, except that three-layer graphene was formed.

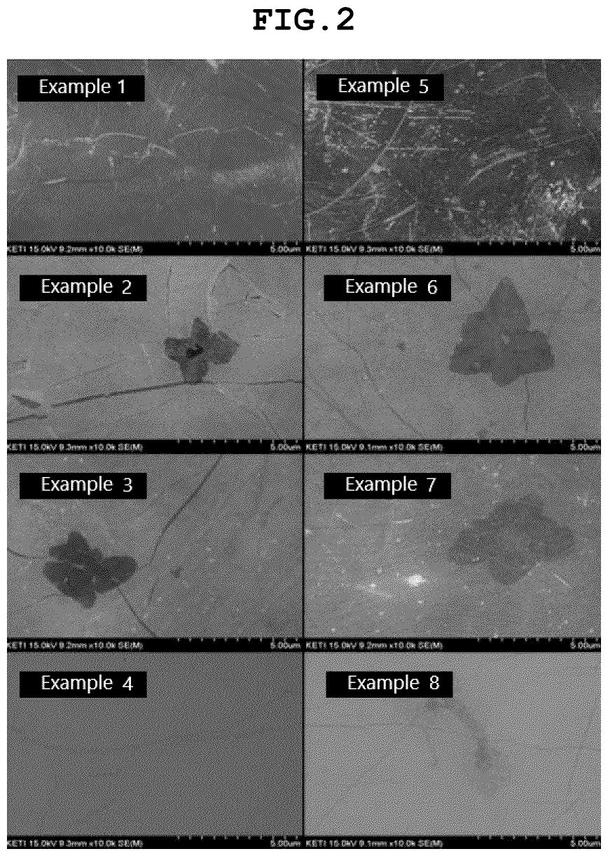

Images of the graphene thin films manufactured through Examples 1 to 8 taken using a scanning electron microscope (SEM) are illustrated in FIG. 2.

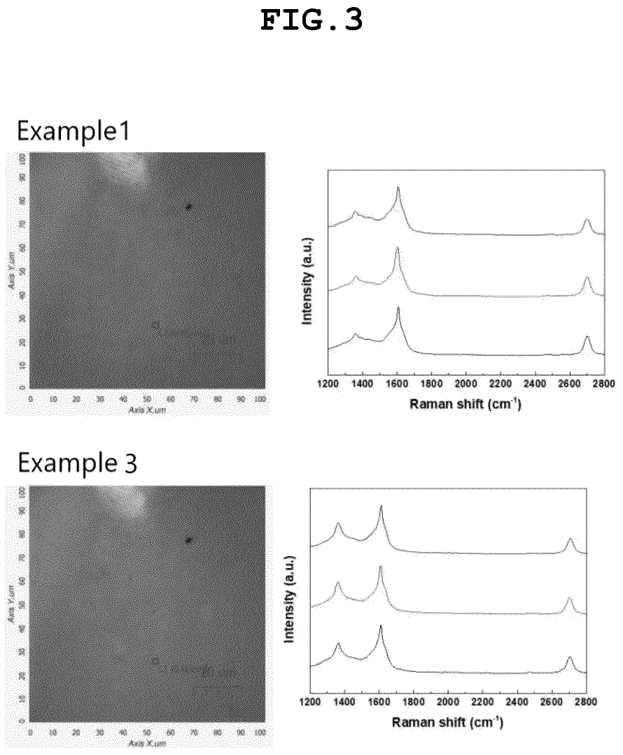

Additionally, images of the graphene thin films manufactured through Examples 1 to 8 analyzed by Raman spectroscopy and graphs showing the results of analysis are illustrated in FIGS. 3 to 6.

As illustrated in FIG. 2, according to the SEM results of the graphene thin films for pellicle materials manufactured through Examples 1 to 8 of the present disclosure, Examples 4 and 8 at the bottom of FIG. 2 show graphene treated under the harshest conditions. Judging from the fact that the boundaries of wrinkles and seeds (flower shape) of graphene are more blurred compared to Examples 1 and 5 at the top of FIG. 2, it can be confirmed that graphene was etched.

Additionally, as illustrated in FIGS. 3 to 6, a peak appearing in a 1350 cm⁻¹ region is a D peak, which occurs when a hexagonal lattice structure of graphene is broken, and tends to grow as defects increase.

Additionally, a peak appearing in a 1580 to 1650 cm⁻¹ region is a G peak, which commonly appears in graphite-based materials, and detects a scattering signal of carbons that form sp2 bonds.

Additionally, a peak appearing at 2350 cm⁻¹ is a 2D peak and indicates the number of layers.

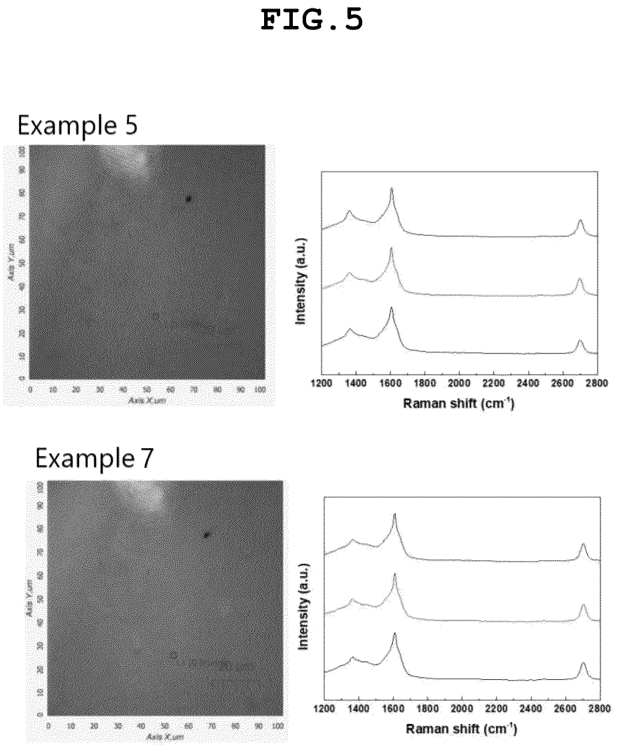

In the case of Example 1 in FIG. 3 and Example 5 in FIG. 5, it can be seen that as ozone treatment conditions become harsher (increased treatment time and increased temperature), the D peak increases (increased defects).

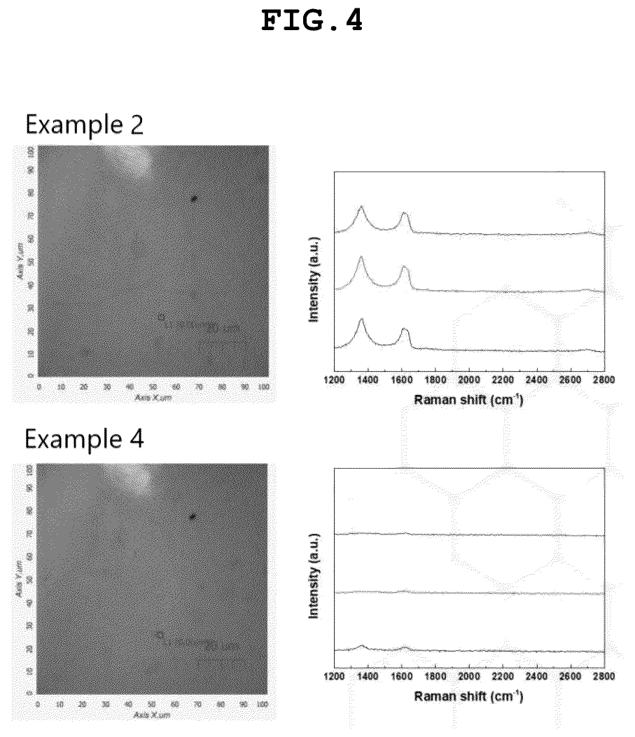

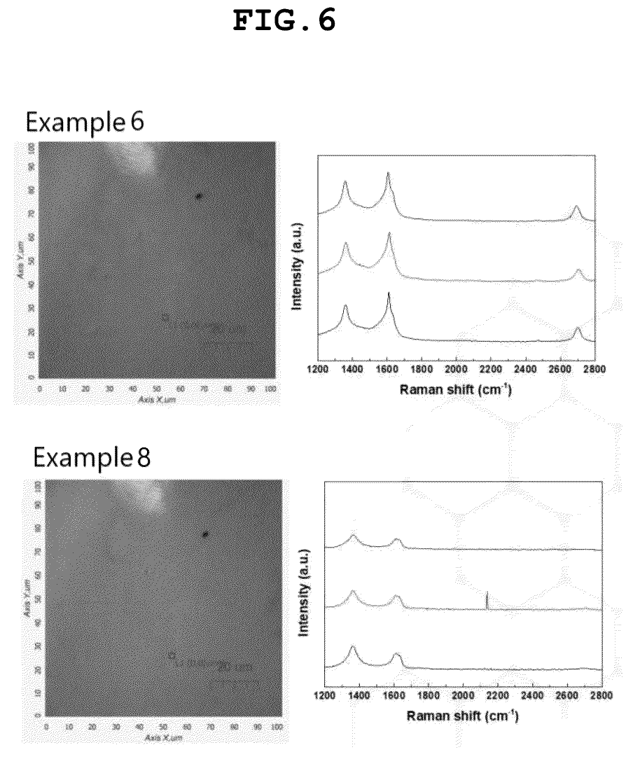

Additionally, in the case of Example 4 in FIG. 4 and Example 8 in FIG. 6, no picks occur because graphene was removed.

Therefore, the method for manufacturing the graphene thin film for the pellicle material using ozone gas according to the present disclosure enables easy control of the thickness of the graphene thin film, and provides a graphene thin film which exhibits excellent extreme ultraviolet transmittance and uniformity, maintains mechanical strength because damage to the graphene layer is suppressed during the etching process, and on which a capping layer can be uniformly deposited though surface functionalization.

What is claimed is:

1. A method for manufacturing a graphene thin film for a pellicle material using ozone gas, the method comprising:
a graphene forming step of forming graphene on an upper surface of a substrate;
an ozone treatment step of exposing the graphene layer formed in the graphene forming step to ozone; and
an etching step of heat-treating and etching the ozone-treated graphene layer.

2. The method of claim 1, wherein the ozone treatment step is performed by exposing the graphene layer formed in the graphene forming step to ozone at 100° C. to 400° C. for 10 to 600 seconds in an oxygen mixture gas atmosphere.

3. The method of claim 2, wherein the oxygen mixture gas is composed of oxygen and nitrogen in a weight ratio of 97:3 and is injected at 900 to 1100 sccm.

4. The method of claim 1, wherein the ozone has a concentration of 50 to 500 g/Nm³.

5. The method of claim 1, wherein the etching step is performed by heat-treating the graphene layer ozone-treated in the ozone treatment step at 400° C. to 1000° C. for 1 to 120 minutes in a hydrogen gas atmosphere.

6. The method of claim 5, wherein the hydrogen gas is injected at 10 to 500 sccm.

7. The method of claim 1, wherein the ozone treatment step and the etching step are repeated until a thickness of the graphene film manufactured through the etching step reaches 10 to 15 nm.
